(19) United States
(12) Patent Application Publication
(10) Pub. No.: US 2019/0284683 A1
(43) Pub. Date: Sep. 19, 2019

(54) APPARATUS AND METHODS FOR REDUCED-ARC SPUTTERING

(71) Applicant: CORNING INCORPORATED, CORNING, NY (US)

(72) Inventors: Xu Ouyang, Painted Post, NY (US); Ye Guang Pan, Vancouver, WA (US)

(73) Assignee: CORNING INCORPORATED, CORNING, NY (US)

(21) Appl. No.: 16/335,383

(22) PCT Filed: Sep. 20, 2017
(86) PCT No.: PCT/US17/52365

§ 371 Date: Mar. 21, 2019

Related U.S. Application Data
(60) Provisional application No. 62/400,234, filed on Sep. 27, 2016.

(51) Int. Cl. C23C 14/50; C23C 14/34; H01J 37/32; H01J 37/34

(52) U.S. Cl. CPC C23C 14/505; H01J 37/3414; H01J 37/32715; C23C 14/3407

(57) ABSTRACT

An apparatus designed to sputter a material onto a plurality of substrates includes a rotating metal frame, a plurality of carriers, and an insulator disposed between the metal frame and the plurality of carriers. The plurality of carriers are designed to hold one or more fixtures that secure the plurality of substrates, and each of the plurality of carriers is designed to couple to the metal frame. The insulator is disposed between the metal frame and the plurality of carriers at locations where the plurality of carriers are coupled to the metal frame such that the plurality of carriers are electrically isolated from the metal frame.

### CROSS-REFERENCE TO RELATED APPLICATIONS

This application claims the benefit of priority under 35 U.S.C. § 119 of U.S. Provisional Application Ser. No. 62/400,234 filed on Sep. 27, 2016, the content of which is relied upon and incorporated herein by reference in its entirety.

### BACKGROUND

### Field

The present disclosure relates to embodiments of an apparatus and related processes for sputter deposition and, more particularly, to apparatus and related processes to reduce or eliminate arcing during sputter deposition.

### Background

Sputter deposition is a physical vapor deposition (PVD) method to deposit thin films of a material on a substrate. Sputtering involves ejecting material from a target that is a source onto the substrate, such as a silicon wafer.

Arcs (or arcing) are local events within the sputter chamber that are detrimental to the process. Arcs are high power density short circuits which have the effect of miniature explosions. When they occur on or near the surface of the target material or chamber fixtures they can cause localized melting. This melting can contaminate the source or substrates as well as degrade the target and coating structure.

### BRIEF SUMMARY

The present disclosure is directed to apparatuses for sputtering, support structures for use in the apparatuses, and related methods.

In some embodiments, an apparatus includes a rotatable metal frame, a plurality of carriers, and an insulator disposed between the metal frame and the plurality of carriers. The plurality of carriers are designed to hold one or more fixtures that secure a plurality of substrates, and each of the plurality of carriers is designed to couple to the metal frame. The insulator is disposed between the metal frame and the plurality of carriers at locations where the plurality of carriers are coupled to the metal frame such that the insulator electrically isolates each of the plurality of metal carriers from the metal frame. The apparatus is designed to sputter a material onto the plurality of substrates.

In some embodiments, the insulator includes a ceramic material.

In some embodiments, the ceramic material is at least one millimeter thick.

In some embodiments, the plurality of carriers are removably coupled to the metal frame.

In some embodiments, the insulator includes a plastic material that maintains its physical and chemical properties up to a temperature of 300 degrees C.

In some embodiments, the plastic material comprises polytetrafluoroethylene (Teflon), polyimide, polyether ether ketone (PEEK), PolyAmide-Imide, PolyEtherImide, Ceramic-Filled PEEK, Polybutylene Terephthalate (PBT) Polyester, or PolyBenzImidazole.

In some embodiments, the metal frame is arranged as a polyhedron.

In some embodiments, the polyhedron comprises between 13 and 52 faces.

In some embodiments, each face of the polyhedron is configured to couple with a given metal carrier of the plurality of metal carriers.

In some embodiments, each of the plurality of metal carriers has a floating electrical potential.

In some embodiments, the presence of the insulator substantially reduces the occurrence of arcing at the exposed surface of the plurality of metal carriers.

In some embodiments, the insulator coats a portion of the plurality of metal carriers at the locations where the plurality of metal carriers are removably coupled to the metal frame.

In some embodiments, the insulator coats a portion of the metal frame at the locations where the plurality of metal carriers are removably coupled to the metal frame.

In some embodiments, the insulator coats both a portion of the plurality of metal carriers and a portion of the metal frame at the locations where the plurality of metal carriers are removably coupled to the metal frame.

In some embodiments, the insulator is an integral part of the metal frame.

In some embodiments, the insulator is an integral part of each of the plurality of metal carriers.

In some embodiments, the insulator is an integral part of the metal frame and each of the plurality of metal carriers.

In some embodiments, the apparatus further includes a pair of sputtering targets, where a first target of the pair of sputtering targets receives a positive voltage bias while a second target of the pair of sputtering targets receives a negative voltage bias.

In some embodiments, the insulator comprises a plastic material that maintains its physical and chemical properties up to a temperature of 300 degrees C.

In some embodiments, a method of loading substrates into a sputter deposition system includes loading one or more substrates onto a fixture. The fixture includes a plurality of segments where each segment holds one substrate of the one or more substrates. The method further includes attaching the fixture onto a metal carrier. The metal carrier is designed to hold a plurality of fixtures. The method further includes attaching the metal carrier to a rotatable metal frame of the sputter deposition system. The metal carrier is electrically isolated from the metal frame by an insulating material between the carrier and the frame.

In some embodiments, the method further includes exposing the one or more substrates and a bare metal surface of the metal carrier to sputtering conditions while the rotatable metal frame is rotating.

### BRIEF DESCRIPTION OF THE DRAWINGS

The accompanying figures, which are incorporated herein, form part of the specification and illustrate embodiments of the present disclosure. Together with the description, the figures further serve to explain the principles of and to enable a person skilled in the relevant art(s) to make and use the disclosed embodiments. These figures are intended to be illustrative, not limiting. Although the disclosure is generally described in the context of these embodiments, it should be understood that it is not intended to limit the scope of the disclosure to these particular embodiments. In the drawings, like reference numbers indicate identical or functionally similar elements.

FIG. 1 illustrates a sputter deposition system, according to some embodiments.

FIG. 2A illustrates a cross-section view of a substrate carrier and a frame with Kapton tape on the substrate carrier.

FIG. 2B illustrates a cross-section view of insulation located between a substrate carrier and a frame, according to some embodiments.

FIG. 3A illustrates a substrate carrier having insulative portions that couple to a frame, according to some embodiments.

FIG. 3B illustrates a frame having insulative portions at locations where a substrate carrier couples to the frame, according to some embodiments.

FIGS. 4A-4C illustrate cross sections of a substrate carrier coupling to a frame, according to some embodiments.

FIG. 5 illustrates a flow chart of a method for loading substrates, according to some embodiments.

FIG. 6 illustrates a flow chart of a sputter deposition process, according to some embodiments.

FIG. 7 illustrates discharge potentials during a sputter process.

### DETAILED DESCRIPTION

Embodiments of the present disclosure are described in detail herein with reference to embodiments thereof as illustrated in the accompanying drawings, in which like reference numerals are used to indicate identical or functionally similar elements. References to “some embodiments,” “in certain embodiments,” “one embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with one embodiments, it is submitted that it is within the knowledge of one skilled in the art to affect such feature, structure, or characteristic in connection with other embodiments whether or not explicitly described.

Where a range of numerical values is recited herein, comprising upper and lower values, unless otherwise stated in specific circumstances, the range is intended to include the endpoints thereof, and all integers and fractions within the range. It is not intended that the scope of the claims be limited to the specific values recited when defining a range. Further, when an amount, concentration, or other value or parameter is given as a range, one or more preferred ranges or a list of upper preferable values and lower preferable values, this is to be understood as specifically disclosing all ranges formed from any pair of any upper range limit or preferred value and any lower range limit or preferred value, regardless of whether such pairs are separately disclosed. Finally, when the term “about” is used in describing a value or an end-point of a range, the disclosure should be understood to include the specific value or end-point referred to. When a numerical value or end-point of a range does not recite “about,” the numerical value or end-point of a range is intended to include two embodiments: one modified by “about,” and one not modified by “about.”

As used herein, the term “about” means that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art.

As used herein, “comprising” is an open-ended transitional phrase. A list of elements following the transitional phrase “comprising” is a non-exclusive list, such that elements in addition to those specifically recited in the list may also be present.

The term “or,” as used herein, is inclusive; more specifically, the phrase “A or B” means “A, B, or both A and B.” Exclusive “or” is designated herein by terms such as “either A or B” and “one of A or B,” for example.

The indefinite articles “a” and “an” to describe an element or component means that one or at least one of these elements or components is present. Although these articles are conventionally employed to signify that the modified noun is a singular noun, as used herein the articles “a” and “an” also include the plural, unless otherwise stated in specific instances. Similarly, the definite article “the,” as used herein, also signifies that the modified noun may be singular or plural, again unless otherwise stated in specific instances.

Directional terms as used herein—for example up, down, right, left, front, back, top, bottom—are made only with reference to the figures as drawn and are not intended to imply absolute orientation.

The term “wherein” is used as an open-ended transitional phrase, to introduce a recitation of a series of characteristics of the structure.

The following examples are illustrative, but not limiting, of the present disclosure. Other suitable modifications and adaptations of the variety of conditions and parameters normally encountered in the field, and which would be apparent to those skilled in the art, are within the spirit and scope of the disclosure.

Sputter deposition is a physical vapor deposition (PVD) method of thin film deposition by sputtering. “Sputtering” involves ejecting particles of material from a “target” (also referred to as a “source”) onto a “substrate” such as a silicon wafer or glass substrate. Resputtering is re-emission of the deposited material during the deposition process by ion or atom bombardment.

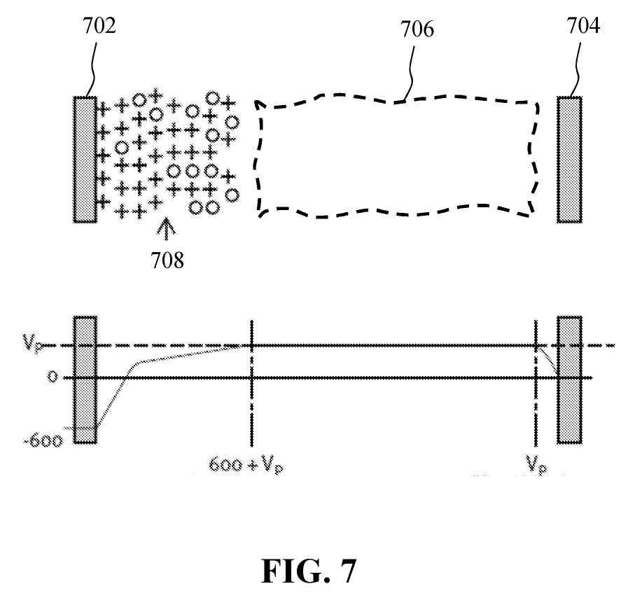

Sputtered atoms ejected from the target can have a wide energy distribution, typically up to tens of electron volts (eV). FIG. 7 illustrates the charge vs. potential in a typical glow discharge configuration. Through various mechanisms, the areas near the target 702 and an anode 704 are stripped of electrons and a surface charge is built up. These areas are known as the “sheath.” As distance increases away from either target 702 or anode 704, the charge balance returns to a more neutral value (e.g., Vₚ as illustrated in FIG. 7.) The potential across a plasma glow region 706 is nearly constant and almost all of the electric field potential occurs in the sheath. A cathode sheath region 708 (also known as the cathode dark space) supplies the basic energy for sputtering. Most ions are produced in the negative cathode sheath region. These ions are accelerated by the sheath potential and bombard the target surface. This bombardment is what ejects the target material.

A sputtered atom may ballistically fly from the target in a straight line to impact energetically on a substrate or on a part of the sputtering apparatus. Sufficiently energetic impact may cause resputtering. At higher gas pressures, sputtered particles may collide with gas atoms that act as a moderator. In this case, sputtered particles may move diffusively, reaching the substrates or vacuum chamber wall and condensing after undergoing a random walk. The entire range from high-energy ballistic impact to low-energy thermalized motion is accessible by changing the background gas pressure. Typically, a small fraction, on the order of 1%, of the ejected particles are ionized.

Inert gases such as argon are often used as a sputtering gas—a stream of argon atoms is directed at the target, such that the impact of argon on the target ejects a particle of material from the target. For efficient momentum transfer, the atomic weight of the sputtering gas should be close to the atomic weight of the target, so for sputtering light elements neon is preferable, while for heavy elements krypton or xenon are used. Reactive gases can also be used to sputter compounds. The compound can be formed on the target surface, in-flight or on the substrate depending on the process parameters.

The availability of many parameters that control sputter deposition make it a complex process, but also allow for a large degree of control over the growth and microstructure of the film. While specific sputtering mechanisms are described herein, any suitable sputtering mechanism may be used.

Sputtering of materials onto various targets, including onto glass targets, allows for the deposition of thin films with a high degree of control over the resulting thickness of the film. One type of sputtering system is a rotary drum sputter system designed to sputter onto a plurality of substrates. The substrates are secured to fixtures that are in-turn secured to large substrate carriers. Each substrate carrier may then be removably coupled to a rotating frame. During deposition, the frame rotates. As the frame rotates, the substrates are sequentially exposed to different conditions. As the substrates pass under targets, particles from the targets may be sputtered onto the substrates. The substrates may optionally pass through a reactive gas or plasma region and/or an inert gas region where sputtered particles are not being deposited. Any reactive gas or plasma present in such regions may react with particles previously deposited by sputtering. Oxygen and nitrogen plasma are commonly used to turn sputter deposited metal layers into oxides or nitrides of the metal.

One problem that can arise with some sputtering systems is arcing. Arcs are local events within the sputter chamber that are detrimental to the process. Arcs are high power density short circuits which have the effect of miniature explosions. Arcing can cause local melting of any material near the arc, including target material, substrate material, deposited material, and the material of the sputtering system itself. Melted material may be ejected. Melted material may damage the material being processed, and may accumulate on other surfaces. The melted material may contaminate or degrade the target, the substrate, and any material deposited on the substrate.

Different types of arcing may occur. Two major types of arcing in drum sputter systems are arcing on the target, and arcing between carriers.

One way to reduce or prevent arcing at the surface of the substrate carriers and fixtures is to apply Kapton tape across the entire surface of the substrate carrier that is exposed to the plasma and/or ions in the sputtering chamber. By protecting the metal surface from the plasma and ions, arcing is substantially reduced. However, this technique is both time consuming and detrimental to the process because out-gassing of the adhesive may create un-removable stains on the substrates.

Prior to the present disclosure, the root cause of the arcing has not been researched and solved. Arcing may occur where two conductive parts having a sufficiently large electrical potential difference are located sufficiently close to each other. Without being bound to any theory, it is believed that each carrier in a rotary drum sputter system is typically electrically isolated, from the drum frame to which it is coupled, by native oxides of the drum frame and/or the carrier. So, each carrier is electrically isolated, and has a floating electrical potential. Exposure to plasma and/or ions causes an electrical potential to build up on each carrier. Because each carrier is exposed to the same conditions, this build up occurs at roughly the same rate on each carrier. So, there is not a large potential difference between carriers, and arcing between carriers does not initially occur. But, in a rotary drum sputter system, movement and vibration occur. The contact resistance between the carrier and the drum frame may change due to imperfect coupling between the parts, or due to vibrations as the metal frame rotates within the sputter chamber. Sometimes, the thin native oxide that electrically isolates the carrier from the drum may break down, allowing current to flow between a particular carrier and the drum, which can dramatically change the electrical potential of that carrier relative to neighboring carriers. If the electrical potential difference between neighboring carriers is sufficiently large, arcing may occur between the carriers.

According to some embodiments, an electrically insulative material is placed between the substrate carriers and the drum frame at the locations where the substrate carriers are removably coupled to the frame. This insulative material prevents electrical contact between the carriers and the frame, thereby avoiding the type of arcing described above. Further details and advantages are provided herein.

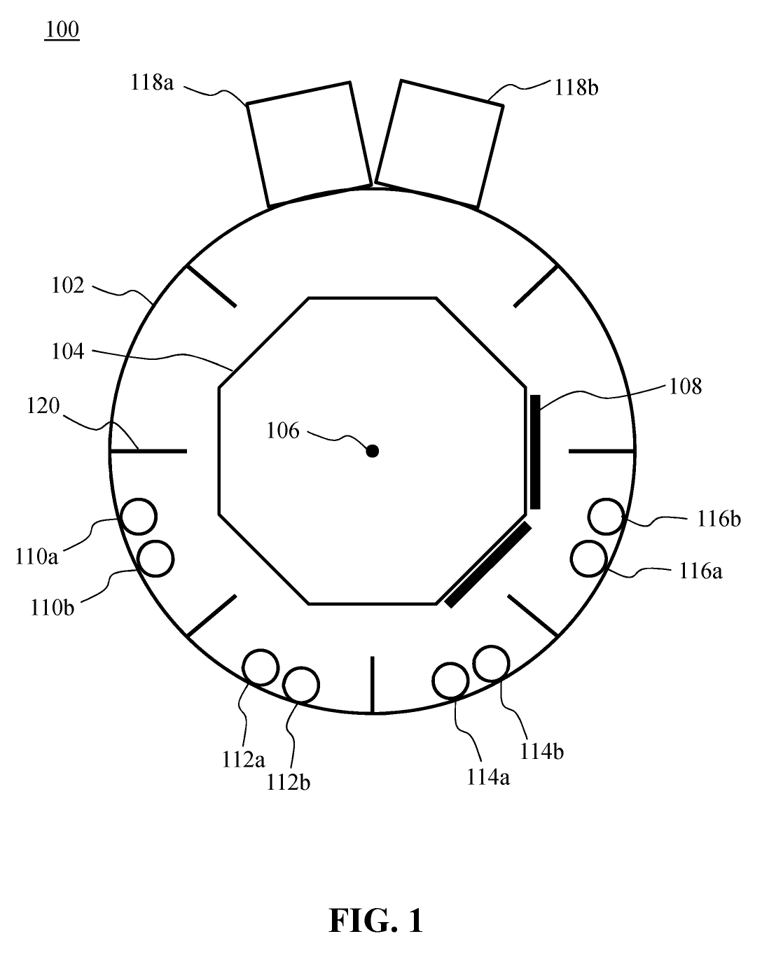

FIG. 1 illustrates a top-down view of an example sputter deposition system 100 for sputtering a material onto a plurality of substrates. Sputter deposition system 100 includes a chamber 102 within which the sputtering of the material occurs. The pressure within the chamber during a sputter process may be between 1 mTorr and 10 mTorr. Although chamber 102 is illustrated as being circular, this is not required and any shape of chamber may be used.

Within chamber 102 is a frame 104, according to some embodiments. Frame 104 is a metallic material, such as aluminum, stainless steel, or titanium, to name a few examples. Frame 104 may be designed to rotate about an axis 106. In some embodiments, frame 104 rotates at a speed between 5 and 10 meters per second. In another embodiment, frame 104 rotates at a speed between 0 and 100 RPM. Frame 104 may be characterized by a having a polyhedron shape, where each face of the polyhedron is designed to couple to a substrate carrier 108, according to some embodiments. In the example illustrated in FIG. 1, frame 104 has an octagonal shape. Frame 104 may have any number of faces where each face is capable of coupling with a substrate carrier 108. In some examples, frame 104 has anywhere between 7 and 91 faces, for example.

Each substrate carrier 108 is designed to hold one or more fixtures, with each fixture holding one or more substrates. In this way, many substrates may be arranged within chamber 102 to have various thin material films deposited upon them. The rotation of frame 104 causes the substrates to be subjected to various portions of chamber 102 during the procedure. Different portions of chamber 102 may include different sputtering targets and/or different reactive gases. For example, some portions of chamber 102 may be defined by having pairs of sputtering targets such as 110a and 110b, 112a and 112b, 114a and 114b, and 116a and 116b. Each pair of sputtering targets includes a pure or nearly pure form of a material to be deposited onto the surface of the substrates. Some common sputtering targets include silicon (Si), aluminum (Al), tantalum (Ta), zirconium (Zr), niobium (Nb), gold (Au), titanium (Ti), and chromium (Cr), to name a few examples. The targets may be arranged in pairs so that a positive voltage is applied to one sputtering target (for example 110a) while a negative voltage is applied to the other corresponding sputtering target (for example 110b) of the same pair. An inert gas such as argon or xenon may be used in chamber 102 around the various sputtering targets 110a, 110b, 112a, 112b, 114a, 114b, 116a, and 116b. Note that although only 4 pairs of sputtering targets are illustrated, any number of sputtering targets may be used within chamber 102. In some embodiments, each sputtering target pair is separated from the others using walls 120. Although paired sputtering targets that eject material based on applied voltage between the targets are illustrated, any suitable sputtering arrangement may be used.

According to some embodiments, another portion of chamber 102 may include inductively coupled plasma sources 118a and 118b to generate a plasma using reactive gases such as oxygen and nitrogen. This reactive region can cause metal films deposited from any of the sputtering targets to be oxidized or nitrified. For example, an aluminum film may become aluminum oxide (Al₂O₃) or aluminum nitride (AlN).

Each substrate carrier 108 may be removably coupled to a given face of frame 104 using a variety of techniques. In one example, each substrate carrier 108 hooks on to portions of frame 104 for easier loading and unloading of the substrate carriers. Both the non-permanent coupling between frame 104 and substrate carrier 108 and the rotation of frame 104 contribute to an unstable contact resistance between frame 104 and each of substrate carriers 108. This unstable contact resistance can cause local build-up of charge on regions of substrate carrier 108, which can ultimately lead to arcing at these regions as the built-up charge discharges. In order to eliminate this build-up of charge, each substrate carrier 108 is electrically isolated from frame 104 using an insulative material between frame 104 and each substrate carrier 108, according to some embodiments.

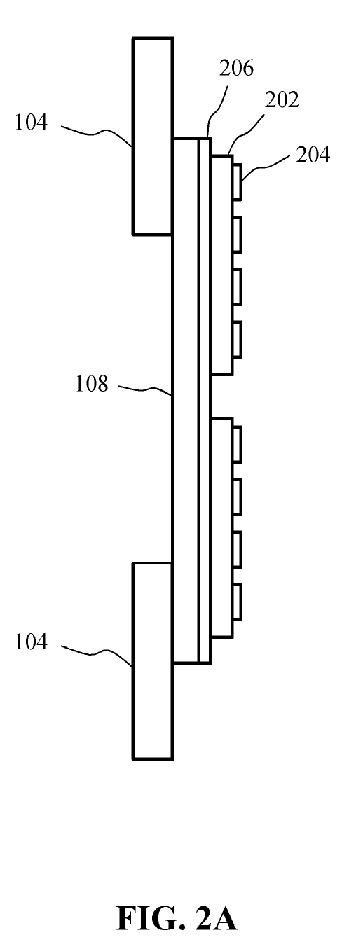

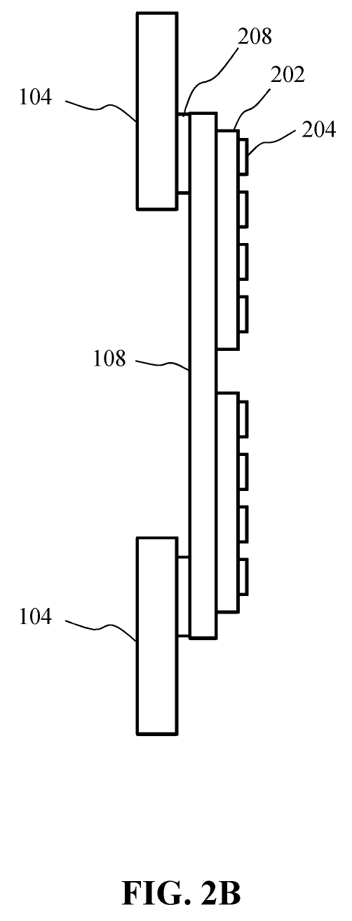

FIG. 2A illustrates an example cross section of the coupling between frame 104 and a given substrate carrier 108. Substrate carrier 108 includes one or more fixtures 202, and each fixture holds one or more substrates 204. Substrates 204 may be semiconductor wafers, such as silicon, indium phosphide, or gallium arsenide, or substrates 204 may be glass. Each fixture 202 may also be metal, such that arcing can also occur on fixture 202 or between fixture 202 and substrate carrier 108.

A layer of adhesive 206 may be used to cover the surface of substrate carrier 108 between substrate carrier 108 and each fixture 202. Adhesive 206 is commonly Kapton tape. Although the presence of adhesive 206 may reduce arcing at the surface of substrate carrier 108 (by protecting the surface from the plasma energy), there are many downsides to including adhesive 206. First, the application of adhesive 206 is time consuming, and needs to be re-applied between each sputtering run. It may take between 20 and 40 minutes to put adhesive 206 over the surface of substrate carrier 108. The constant re-application of the adhesive is also expensive as the cost of the adhesive may be high. Second, the presence of adhesive 206 causes out-gassing of the material during the sputtering process. The out-gassing reduces the vacuum pumping speed, can contaminate the sputtered material on the substrates, and can form stains on any exposed glass parts.

FIG. 2B illustrates an example cross section of the coupling between frame 104 and a given substrate carrier 108, according to some embodiments. As discussed above in FIG. 2A, substrate carrier 108 includes one or more fixtures 202, and each fixture holds one or more substrates 204.

At each location where frame 104 is to couple with substrate carrier 108, an insulative material 208 is disposed, according to some embodiments. Insulative material 206 electrically isolates substrate carrier 108 from frame 104, such that substrate carrier 108 has a floating electrical potential. Insulative material 206 may be a ceramic material or a plastic material that maintains its physical and chemical properties up to a temperature of 300 degrees C. Example ceramic materials for insulative material 208 include: Photoveel or Photoveel II series material (available from Ferrotec, Santa Clara, Calif.); Remcolox™ and Super-Heat ceramics (available from Aremco, Valley Cottage, N.Y.); Duratec 750® Machinable Ceramic (available from Goodfellow, Coraopolis, Pa.); Mykroy/Mycalex (MM) (available from San Diego Plastics, National City, Calif.); Alumina (AL203) 99.5%; Alumina Oxide; Aluminum Nitride (AlN); Beryllium; Boron Nitride; Macor® Machinable Glass Ceramic (available from Corning Incorporated, Corning, N.Y.); Silicon Nitride; Zirconia Ceramic (ZrO2); and Fused Silica. Example plastic materials for insulative material 208 include: polytetrafluoroethylene (Teflon); polyimide (for example, Kapton®, Plavis®, Dupont Vespel®, Duratron®); Dupont Zytel® PLUS; PolyAmide-Imide (for example, Torlon® PAI); PolyEtherImide (for example, Ultem® PEI); Ceramic-Filled PEEK, for example EPM-2204U-W; Semitron® CMP; PBT Polyester (for example, Hydex 4101®); Durostone ® FRP; Ultramid® Endure; polyether ether ketone (PEEK); and PolyBenzImidazole (for example, Celazole® PBI). In another embodiment, insulative material 208 comprises a thick (at least one micrometer thick) metal oxide or metal nitride. It should be noted that a native oxide on either or both metal surfaces of frame 104 and substrate carrier 108 is not thick enough to act as an insulative material because it would not electrically isolate substrate carrier 108 from frame 104.

According to some embodiments, insulative material 208 has a thickness between 0.5 mm and 5 mm. According to some embodiments, insulative material 208 has a thickness of about 1 mm. The thickness of insulative material 208 may be determined based on several factors. If insulative material 208 is too thin, then the repeated use and wear may break or crack insulative material 208 causing a short between frame 104 and substrate carrier 108. On the other hand, if insulative material 208 is too thick, depending on the material, outgassing from the material may noticeably impact the sputtering procedure in a negative way. A balance is thus maintained between having enough insulative material to isolate substrate carrier 108, while using as little as possible to avoid any detrimental effects caused by outgassing of the material.

Insulative material 206 may be a block of material disposed between frame 104 and substrate carrier 108. In another embodiment, insulative material 208 is a coating around either frame 104 or substrate carrier 108, or both. The coating may only be present at locations where frame 104 couples with substrate carrier 108. This eliminates the need to coat the entire surface of either frame 104 or substrate carrier 108. In another embodiment, insulative material 208 is an integral part of frame 104 or substrate carrier 108, or both.

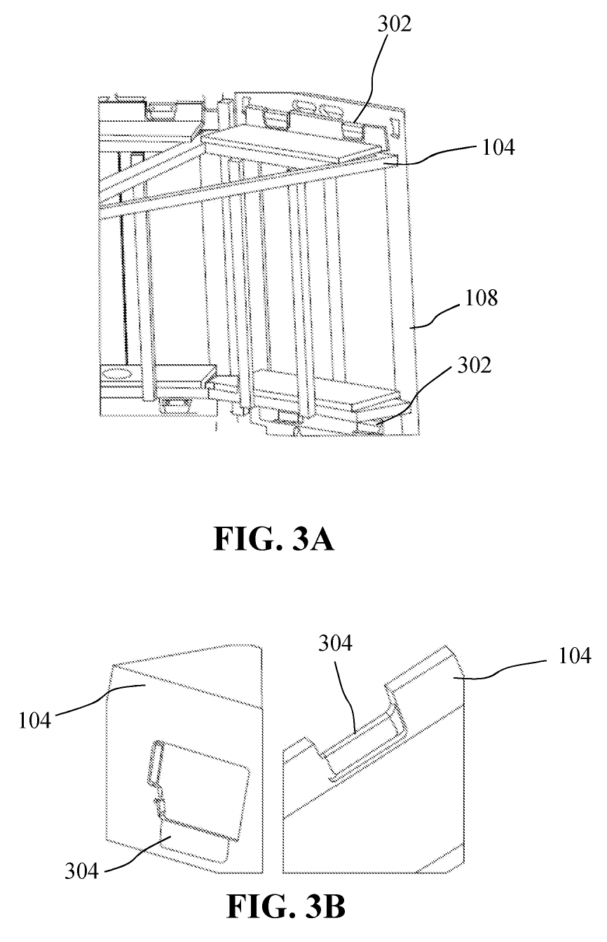

FIG. 3A illustrates an example three-dimensional view of frame 104 having a substrate carrier 108 coupled to it. According to some embodiments, substrate carrier 108 includes a plurality of flanges 302 that each hook into a corresponding opening in frame 104 in order to detachably couple substrate carrier 108 to frame 104. According to some embodiments, each flange 302 comprises an insulative material, such as any of the materials discussed above for insulative material 208. Although only four flanges 302 are illustrated in FIG. 3A, any number of flanges 302 may be used to detachably couple substrate carrier 108 to frame 104.

FIG. 3B illustrates an example three-dimensional view of insulative portions 304 of frame 104, according to some embodiments. Insulative portions 304 may be any of the materials discussed above for insulative material 208. According to some embodiments, substrate carrier 108 rests upon insulative portions 304 when coupled to frame 104. According to some embodiments, each flange 302 comprises an insulative material and rests upon a corresponding insulative portion 304 of frame 104.

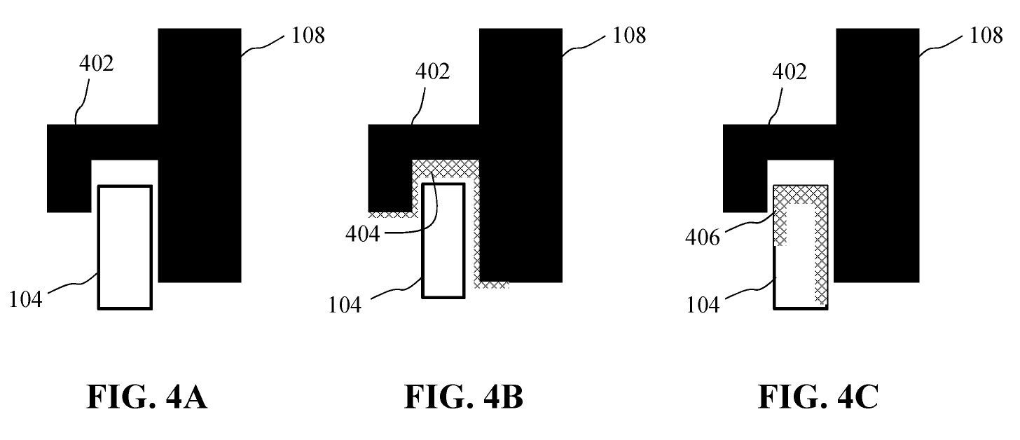

FIGS. 4A-4C illustrate example cross sections of the coupling between substrate carrier 108 and frame 104, according to some embodiments. The coupling illustrated in each of FIGS. 4A-4C involves substrate carrier 108 hooking onto frame 104. Other coupling mechanisms may be used as well. Also, it should be noted that the illustrated coupling between substrate carrier 108 and frame 104 may occur along the top of substrate carrier 108 and/or bottom of substrate carrier 108.

FIG. 4A illustrates substrate carrier 108 having a flange 402 that couples to frame 104. As such, flange 402 of substrate carrier 108 rests upon frame 104 when loading substrate carrier 108 onto frame 104. Due to vibrations from rotation of frame 104, the contact between flange 402 and frame 104 may not be constant, causing changes in the contact resistance between the elements. This may lead to arcing due to changes in the potential of substrate carrier 108.

FIG. 4B illustrates substrate carrier 108 having a flange 402 with an insulative material 404, according to some embodiments. Insulative material 404 may be a coating on flange 402 or a block of material attached to flange 402. Insulative material 404 provides electrical isolation between substrate carrier 108 and frame 104 when substrate carrier 108 is mounted onto frame 104. In some embodiments, flange 402 is itself an electrically insulative material. Insulative material 404 may be any of the materials discussed above for insulative material 208.

FIG. 4C illustrates substrate carrier 108 having a flange 402 that rests upon frame 104 having an insulative material 406, according to some embodiments. Insulative material 406 may be a coating on frame 104 or a block of material attached to frame 104. Insulative material 406 provides electrical isolation between substrate carrier 108 and frame 104 when substrate carrier 108 is mounted onto frame 104. Insulative material 406 may be any of the materials discussed above for insulative material 208. In some embodiments, both frame 104 and flange 402 include insulative materials such that the mounting of substrate carrier 108 to frame 104 involves contact between two insulative surfaces.

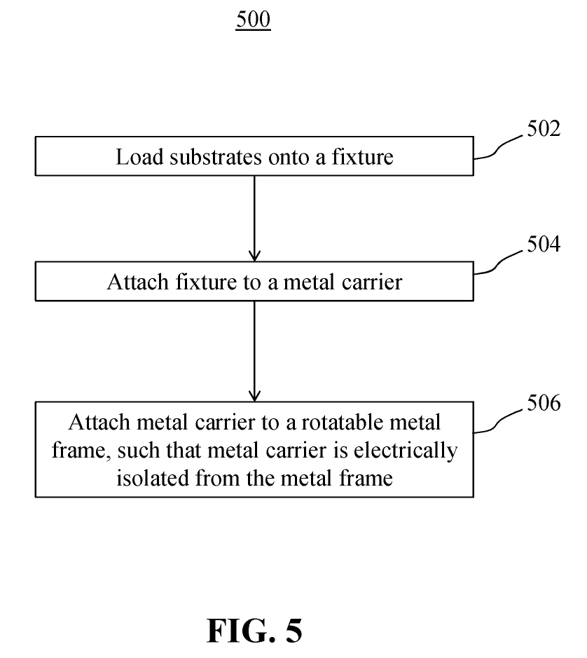

FIG. 5 illustrates an example method 500 of loading substrates into a sputter deposition system, according to some embodiments. The various operations of method 500 may be performed at different locations or at different times.

Method 500 starts at block 502 where one or more substrates are loaded onto a fixture. The fixture may include a plurality of segments where each segment holds a substrate from the one or more substrates. Thus, a single fixture may be designed to hold anywhere between one and ten substrates, for example.

Method 500 continues with block 504 where the fixture is attached to a metal carrier. The metal carrier is designed to hold a plurality of the fixtures. A single metal carrier may be designed to hold anywhere between two and six fixtures, for example. In some embodiments, the fixtures are also metal and the exposed surfaces of the fixtures would be subjected to arcing events along with the exposed surfaces of the metal carrier if not properly electrically isolated according to the principles of the present disclosure.

Method 500 continues with block 506 where the metal carrier is attached to a rotatable metal frame of the sputter deposition system. According to some embodiments, the metal carrier is electrically isolated from the metal frame by an insulating material between the metal carrier and the metal frame. The metal carrier may be hooked onto the metal frame by insulative flanges that are an integral part of the metal carrier. In another embodiment, the metal carrier hooks onto insulative portions that are integral to the metal frame.

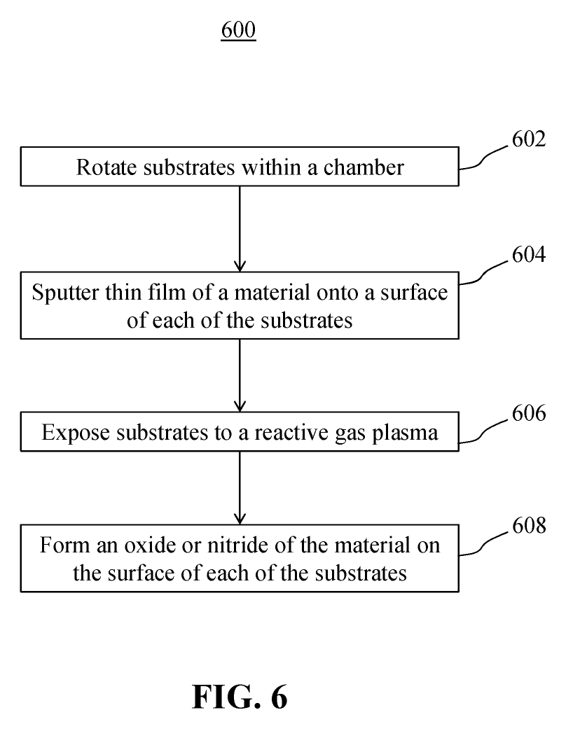

FIG. 6 illustrates an example method 600 of performing a sputter deposition process, according to some embodiments. The various operations of method 600 may be performed using a sputter deposition system such as sputter deposition system 100 as illustrated in FIG. 1.

Method 600 starts at block 602 where substrates are rotated within a chamber. The substrates may be attached to various fixtures and substrate carriers which in turn are coupled to a rotating drum frame. The frame may rotate the substrates at a speed between 0 and 100 RPM, for example.

Method 600 continues with block 604 where a thin film of a material is sputtered on a surface of each of the substrates. The sputtered material may include silicon (Si), aluminum (Al), tantalum (Ta), zirconium (Zr), niobium (Nb), gold (Au), titanium (Ti), and chromium (Cr), to name a few examples. The thickness of the thin film varies based on the parameters used during the sputtering process and the sputtering time, but may be anywhere from 1 nanometer to 1 micrometer, for example. The high energy plasma used during sputtering may cause arcing to occur at the substrate carriers, unless the substrate carriers have been electrically isolated from the drum frame using an insulative material, according to some embodiments.

Method 600 continues with block 606 where the substrates are subjected to a reactive gas plasma in a separate portion of the chamber. Unlike the sputtering gas (typically an inert gas like argon), the reactive gas may include oxygen or nitrogen to name a few examples.

Method 600 continues with block 608 where the exposure to the reactive gas causes the sputtered material on the substrates to oxidize or nitrify, thus forming an oxide or nitride of the material. For example, an aluminum film may become aluminum oxide (Al₂O₃) or aluminum nitride (AlN). In other examples, a silicon film may become silicon dioxide (SiO₂) or silicon nitride (Si₃N₄).

While various embodiments have been described herein, they have been presented by way of example only, and not limitation. It should be apparent that adaptations and modifications are intended to be within the meaning and range of equivalents of the disclosed embodiments, based on the teaching and guidance presented herein. It therefore will be apparent to one skilled in the art that various changes in form and detail can be made to the embodiments disclosed herein without departing from the spirit and scope of the present disclosure. The elements of the embodiments presented herein are not necessarily mutually exclusive, but may be interchanged to meet various needs as would be appreciated by one of skill in the art.

It is to be understood that the phraseology or terminology used herein is for the purpose of description and not of limitation. The breadth and scope of the present disclosure should not be limited by any of the above-described exemplary embodiments, but should be defined only in accordance with the following claims and their equivalents.

1. An apparatus comprising:
a rotatable metal frame;
a plurality of metal carriers, coupled to the metal frame; and
an insulator disposed between the metal frame and each of the plurality of metal carriers at locations where the plurality of carriers are coupled to the metal frame, such that the insulator electrically isolates each of the metal carriers from the metal frame;
wherein each metal carrier is configured to hold one or more fixtures each configured to secure one or more substrates; and
a sputtering chamber.

2. The apparatus of claim 1, wherein the insulator comprises a ceramic material and is at least one millimeter thick.

3. The apparatus of claim 1, wherein the metal carriers are removably coupled to the metal frame.

4. The apparatus of claim 1, wherein the insulator comprises a plastic material that maintains its physical and chemical properties up to a temperature of 300 degrees C.

5. The apparatus of claim 4, wherein the plastic material comprises polytetrafluoroethylene (Teflon), polyimide, polyether ether ketone (PEEK), PolyAmide-Imide, PolyEtherImide, Ceramic-Filled PEEK, polybutylene terephthalate (PBT) Polyester, or PolyBenzImidazole.

6. The apparatus of claim 1, wherein the insulator comprises a metal oxide having a thickness greater than one micrometer.

7. The apparatus of claim 1, wherein the metal frame is has a polyhedron shape.

8. The apparatus of claim 7, wherein the polyhedron comprises between 7 and 91 faces.

9. The apparatus of claim 8, wherein each face is configured to couple with a given metal carrier of the plurality of metal carriers.

10. The apparatus of claim 1, wherein each of the plurality of metal carriers has a floating electrical potential.

11. The apparatus of claim 1, wherein the presence of the insulator substantially reduces the occurrence of arcing at the exposed surface of the plurality of metal carriers.

12. The apparatus of claim 1, wherein the insulator coats a portion of the plurality of metal carriers at the locations where the plurality of metal carriers are coupled to the metal frame.

13. The apparatus of claim 1, wherein the insulator coats a portion of the metal frame at the locations where the plurality of metal carriers are coupled to the metal frame.

14. The apparatus of claim 1, wherein the insulator coats both a portion of the plurality of metal carriers and a portion of the metal frame at the locations where the plurality of metal carriers are coupled to the metal frame.

15. The apparatus of claim 1, wherein the insulator is an integral part of the metal frame.

16. The apparatus of claim 1, wherein the insulator is an integral part of each of the plurality of metal carriers.

17. The apparatus of claim 1, wherein the insulator is an integral part of the metal frame and each of the plurality of metal carriers.

18. The apparatus of claim 1, further comprising a pair of sputtering targets, wherein a first target of the pair of sputtering targets is configured to receive a positive voltage bias while a second target of the pair of sputtering targets is configured to receive a negative voltage bias.

19. A method of loading substrates into a sputter deposition system, the method comprising:
loading one or more substrates onto a fixture;
attaching the fixture onto a metal carrier; and
attaching the metal carrier to a rotatable metal frame of the sputter deposition system, wherein the metal carrier is electrically isolated from the metal frame by an insulating material between the metal carrier and the metal frame.

20. The method of claim 19, further comprising: exposing the one or more substrates and a bare metal surface of the metal carrier to sputtering conditions while the rotatable metal frame is rotating.
